(19) United States
(12) Patent Application Publication
(10) Pub. No.: US 2013/0027894 A1
(43) Pub. Date: Jan. 31, 2013

(54) STIFFNESS ENHANCEMENT OF ELECTRONIC SUBSTRATES USING CIRCUIT COMPONENTS

(71) Applicant: Paul B. Koeneman, Palm Bay, FL (US)

(72) Inventor: Paul B. Koeneman, Palm Bay, FL (US)

(73) Assignee: HARRIS CORPORATION, Melbourne, FL (US)

(21) Appl. No.: 13/191,638

(22) Filed: Jul. 27, 2011

(51) Int. Cl. H05K 7/02; H05K 3/22; H05K 3/34

(52) U.S. Cl. 361/760; 29/832; 29/840

(57) ABSTRACT

Electrical components are mounted on a substrate and a stiffening member is mechanically coupled to the substrate to increase the stiffness of the substrate. The stiffening member includes passive devices that are electrically connected to the electrical components via traces on the substrate. The passive devices can be serially mechanically connected to each other so that the stiffening member extends across at least 60% of the substrate.

### BACKGROUND OF THE INVENTION

1. Statement of the Technical Field

The inventive arrangements relate to electronic substrates, and more particularly to methods for improving the stiffness of such substrates by the use of groupings of electronic devices mounted thereon.

2. Description of the Related Art

Electrical devices are mounted on and interconnected to each other through a substrate, such as a circuit board. The desire for smaller and more capable electronics has led the drive for higher density packaging and hence for greater device densities on substrates. Similarly, the demand for low profile (i.e., thin) packaging is increasing due to the growth of personal electronics, such as cell phones, MP3 players, smart cards and so forth, and hence thinner substrates are desired. As electronics get thinner and interconnect densities increase, substrate warpage becomes an issue of increasing concern.

Multi chip modules (MCMs) are a packaging method that has been successfully employed to increase packaging densities. In an MCM, multiple semiconductor dies, passive devices and active devices are packaged onto a unifying substrate. The result is what appears to be a single chip package. Because of the drive for thinner devices, there is a desire for thinner MCMs. Proprietary devices and aerospace businesses areas examples of fields in which there is a strong push for thin MCMs.

In most current MCMs the stiffness of the substrate dominates over the stiffness of the devices on the substrate. The tolerances are loose enough that substrate warpage is not a significant issue. Further, the interconnect density is low enough that the interconnects are able to withstand stresses from any warpage that does occur. In larger systems, however, stiffener rods are used to limit the flexure of substrates. These stiffener rods introduce added complexity and manufacturing costs into the MCM. Of even more significance in low profile circuits, these stiffener rods increase the thickness of the overall circuit structure. Accordingly, it would be desirable to provide for the stiffening of substrates without needing to introduce stiffener rods.

### SUMMARY OF THE INVENTION

Embodiments of the invention concern electrical substrates with stiffening members made from electrical devices that form a part of the circuit and substrate stiffening methods related thereto.

In one aspect an electrical system is disclosed comprising a substrate, a plurality of host electrical components mounted on the substrate and electrically coupled to traces on the substrate, and at least a stiffening member mechanically coupled to the substrate. The stiffening member increases the stiffness of the substrate and is electrically connected via the traces to at least one of the host electrical components. The stiffening member comprises a plurality of ancillary electrical devices, and these ancillary electrical devices are mechanically bonded to each other with gap filler so as to form the stiffening member. The gap filler has a coefficient of thermal expansion that is within +/−50% of the coefficient of thermal expansion of the substrate. The ancillary electrical devices are preferably passive devices used to provide electrical supporting functions for one or more host electrical components. The stiffening member can include a plurality of electrical contacts that are electrically coupled to corresponding electrical devices of the stiffening member, and the electrical contacts are soldered to corresponding traces on the substrate. In preferred embodiments these ancillary electrical devices are mechanically connected to each other in a serial manner, and the stiffening member extends across at least 60% of the substrate to prevent general warpage of the substrate or at least two millimeters in length for local protection of weak points.

In another aspect a method for increasing the stiffness of an electrical substrate is disclosed, in which a plurality of ancillary electrical devices are mechanically connected to the substrate at locations on the substrate corresponding to a stiffening member for the substrate. The plurality of the ancillary electrical devices are electrically connected to at least one host electrical component. Then, gap filler is disposed into gaps between the plurality of the ancillary electrical devices to mechanically connect the plurality of the ancillary electrical devices together to form the stiffening member for the substrate. In various embodiments the stiffening member includes a plurality of electrical contacts provided by the corresponding ancillary electrical devices of the stiffening member, and the method further includes electrically and mechanically connecting the contacts to corresponding traces on the substrate, such as by soldering or the like. In some embodiments the ancillary electrical devices are discrete devices that are mechanically coupled to each other in situ to form the stiffening member. In preferred embodiments the layout of the ancillary electrical devices is planned so that the ancillary electrical devices are mechanically connected to each other in a serial manner, and the stiffening member extends across at least 60% of the substrate to prevent general warpage of the substrate or at least two millimeters in length for local protection of weak points. The gap filler preferably has a coefficient of thermal expansion that is within +/−50% of the coefficient of thermal expansion of the substrate.

In yet another aspect a method for increasing the stiffness of an electrical substrate is disclosed, in which a location is identified for a stiffening member on the substrate. A plurality of ancillary electrical devices are selected for positioning on the substrate within the identified location for the stiffening member. Traces are routed on the substrate for the plurality of the ancillary electrical devices to electrically connect the plurality of the ancillary electrical devices to host electrical components. The ancillary electrical devices are caused to be embedded within a packaging matrix to form a monolithic component having a stiffness greater than that of the substrate to form the stiffening member. The stiffening member is then soldered to the traces on the substrate at the identified location for the stiffening member to mechanically and electrically connect the stiffening member to the substrate and host electrical components, respectively.

### BRIEF DESCRIPTION OF THE DRAWINGS

Embodiments will be described with reference to the following drawing figures, in which like numerals represent like items throughout the figures, and in which:

FIG. 1 is a top view of a substrate employing various embodiment stiffening devices and in an incomplete state according to an embodiment stiffening method.

FIG. 2 is a cross-sectional view of the substrate shown in FIG. 1 along a line 2-2.

FIG. 3 is a top view of the substrate shown in FIG. 1 in a completed state according to an embodiment stiffening method.

FIG. 4 is a cross-sectional view of the substrate shown in FIG. 4 along a line 4-4.

FIG. 5 is a cross-sectional view of the substrate shown in FIG. 4 along a line 5-5 illustrating another embodiment stiffening method and related device.

FIGS. 6A and 6B illustrate another embodiment stiffening method.

### DETAILED DESCRIPTION

The invention is described with reference to the attached figures. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operation are not shown in detail to avoid obscuring the invention. The invention is not limited by the illustrated ordering of acts or events, as some acts may occur in different orders and/or concurrently with other acts or events. Furthermore, not all illustrated acts or events are required to implement a methodology in accordance with the invention.

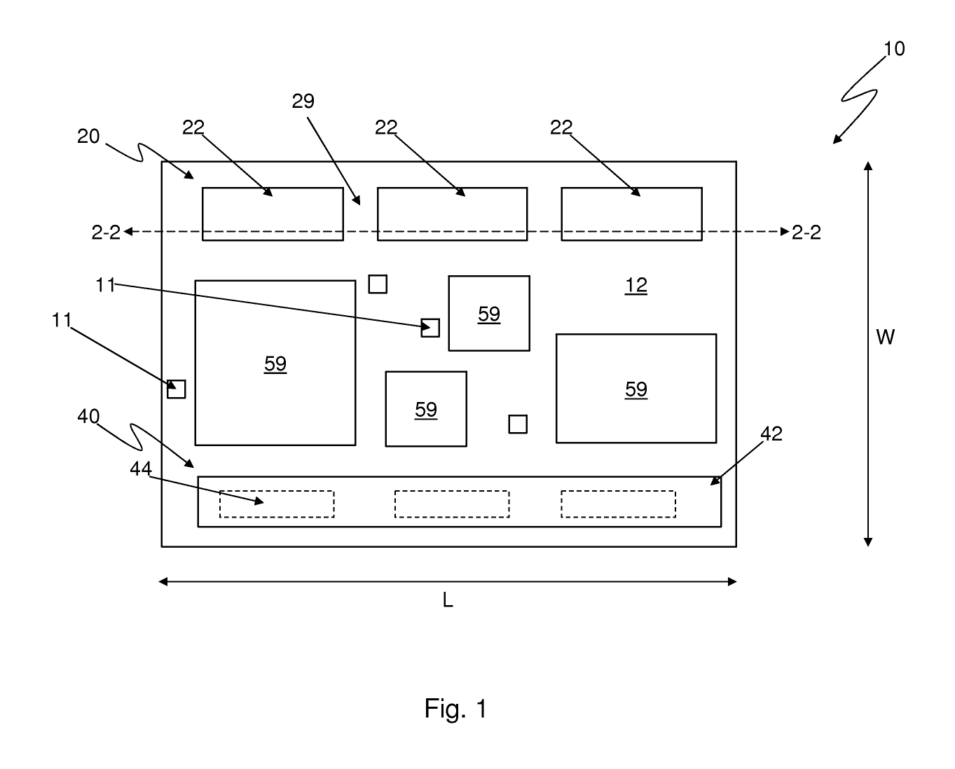

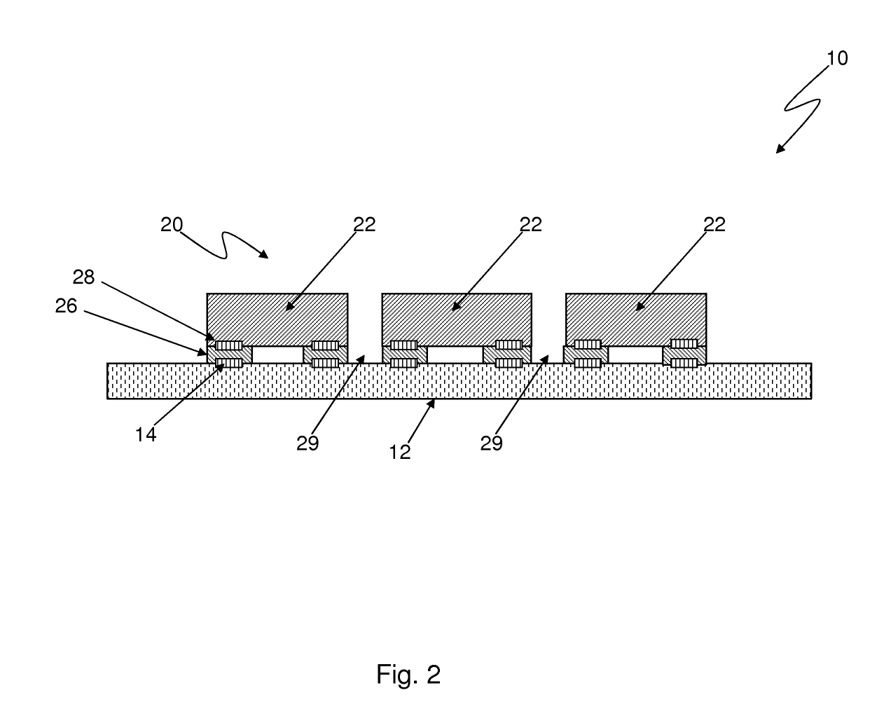

Reference is drawn to FIGS. 1 and 2. A substrate 12 is used as a mechanical support for the various electronics of a circuit 10. The circuit 10 can be, for example, an MCM. The substrate 12 is preferably thin, such as 1 to 10 mils in thickness, to provide a low profile for the circuit 10. Any suitable material for the substrate 12 can be used; a preferred example is liquid crystal polymer (LCP), but other materials known in the art can be employed as well. Circuit electronics are mechanically bonded to the substrate 12 using any suitable means, such as solder, electrically conductive adhesives or the like. The substrate 12 also provides electrical interconnects between the various electronics mounted thereto by way of traces 14, as known in the art.

The circuit 10 will include one or more host electrical components 59, typically integrated circuit (IC) devices, that perform the bulk of the functionality desired of the circuit 10. These host electrical components 59, however, will frequently need ancillary electrical devices 11, 22 and in particular passive components, such as capacitors, inductors, resistors and diodes, although other types of ancillary devices 11, 22 are possible, including other active devices. The ancillary electrical devices 11, 22 are soldered or otherwise electrically coupled to the substrate 12 to provide predetermined electrical support functions in relation to the active host electrical components 59 on the substrate 12. For example, resistors may be used to tie the voltage on a signal line high or low as required for the proper functioning of a host electrical component 59, while capacitors may be used to decouple signal lines from power lines, prevent ringing on signal lines or the like so as to insure proper communications between the host electrical components 59. These ancillary electrical devices 11, 22 may be discrete or may themselves be embedded. A discrete device is a single ancillary electrical device 11, 22 coupled to the substrate 12 and does not have a package of its own. An embedded device, on the other hand, may comprise one or a plurality of ancillary electrical devices 11, 22 often of the same type, that are disposed within their own package.

As shown in FIGS. 1 and 2, in one embodiment discrete ancillary electrical devices 22 are mechanically coupled together in situ on the substrate 12 using, for example, a gap filler, to form a stiffening member 20. This resultant stiffening member 20, which is soldered or otherwise electrically and mechanically coupled to the substrate 12 via the ancillary electrical devices 22 thereof, serves as both an ancillary electrical component of the circuit 10 and as a mechanical reinforcing means to impart rigidity to the substrate 12.

As a first step in this substrate stiffening method, the desired location of the stiffening member 20 on the substrate 12 is determined using any suitable means, such as methods used to determine the position of a conventional stiffening rod. Then, when planning the layout of the various electronics 11, 22, 59 of the circuit 10, a subset 22 of the ancillary electrical devices 11, 22 is selected and the layout of the circuit 10 is planned such that the selected ancillary electrical devices 22 for the host electrical components 59 are disposed across the substrate 12 where stiffening enhancement of the substrate 12 is desired. This may entail any suitable positional arrangement of the selected ancillary electrical devices 22 across the substrate 12, but will typically involve a serial positioning of the ancillary electrical devices 22 along the substrate 12 at positions that correspond to where a conventional stiffening rod would be located. For example, the circuit 10 layout may be planned such that the selected ancillary electrical devices 22 are positioned in a straight line along the substrate 12 adjacent to an edge of the substrate 12. Ancillary electrical devices 22 that have flexibility with respect to distance from their respective host electrical components 59 are thus preferred when selecting ancillary devices 22 and designing such a layout; passive devices 22 are often the most convenient in this respect. Also, ancillary electrical devices 22 that are themselves mechanically rigid (i.e., have a high structural stiffness) are preferred.

The traces 14 on the substrate 12 are routed in a conventional manner so that all ancillary electrical devices 11, 22 are electrically connected as needed to their respective host electrical components 59. By way of example, trace routing methods that are employed for embedded components may be employed to plan the traces 14 for the stiffening member 20. Once the traces 14 are routed and the corresponding substrate 12 provided, host electrical components 59 and their ancillary electrical devices 11, 22, are electrically and mechanically connected to the substrate 12 in a standard manner in accordance with the planned layout of the circuit 10, such as by way of a pick and place machine or the like. Each ancillary electrical device 11, 22 is, for example, soldered or bonded with electrically conductive adhesive to one or more traces 14 on the substrate 12 to electrically connect it to its corresponding host electrical component 59, as well as to mechanically bond it to the substrate 12. Gaps 29 exist between the selected ancillary electrical devices 22 that are arrayed immediately adjacent to each other across the substrate 12. Typical gap 29 sizes are between 0.010 inches (254 micrometers) and 0.020 inches (508 micrometers).

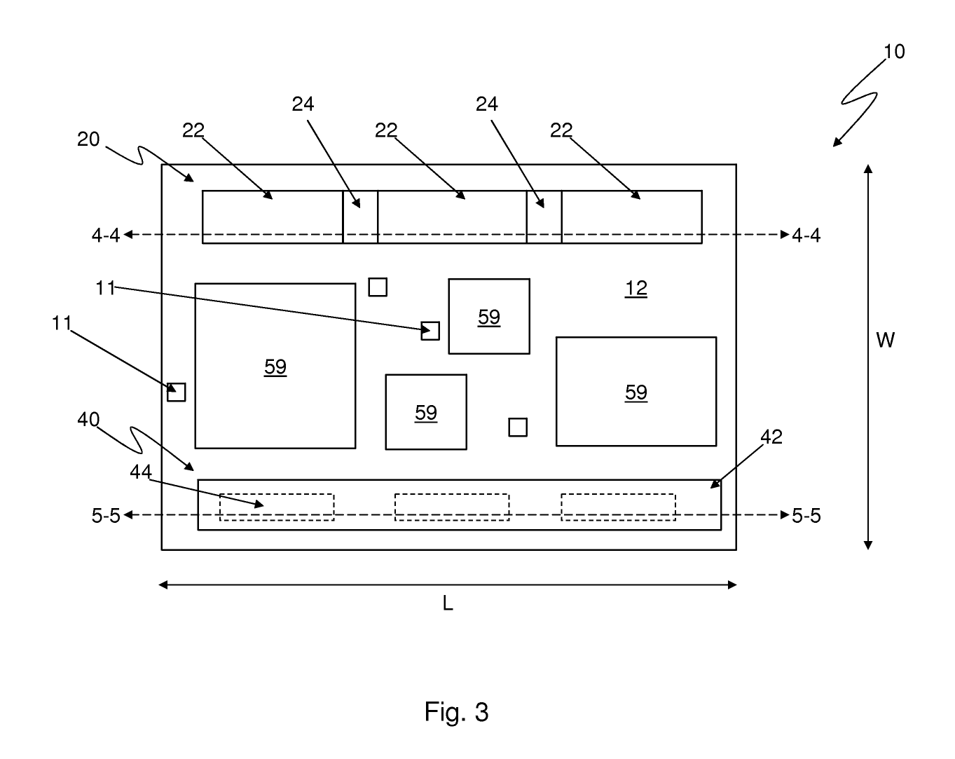

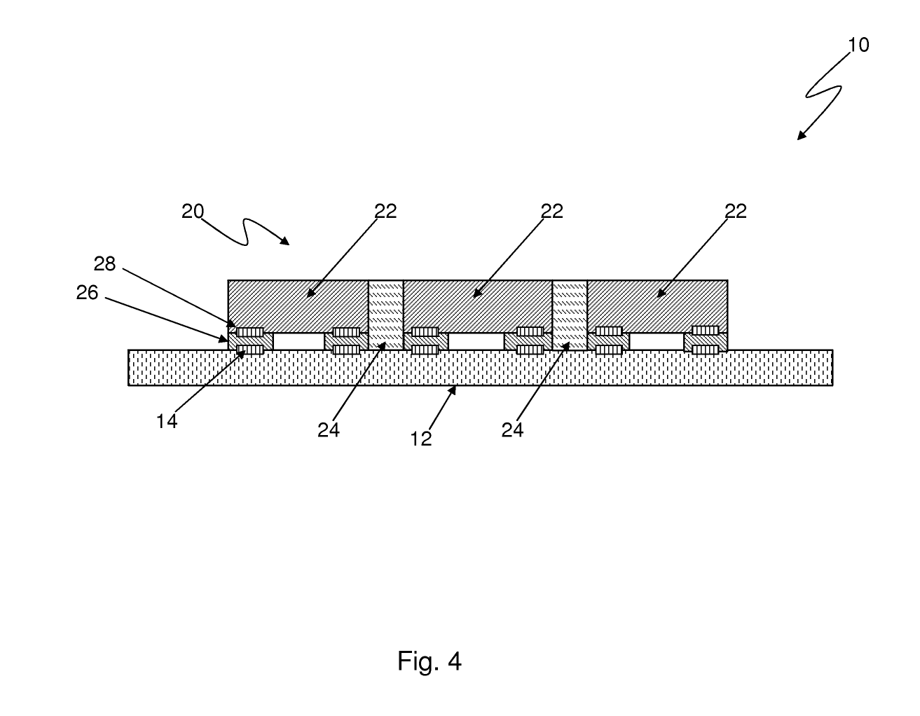

As shown in FIGS. 3 and 4, the gaps 29 are then filled in situ with a gap filler 24 to form a stiffening member 20. The gaps 29 may be filled in any suitable manner that mechanically bonds the selected ancillary electrical devices 22 together to form a stiffening member 20 capable of imparting increased rigidity to the substrate 12. By way of example, plastic or metal spacers respectively sized to each gap 29 may be disposed within the gaps 29 and bonded to corresponding immediately-adjacent ancillary electrical devices 22, such as with epoxy or the like, to serve as gap fillers 24; more specifically, adhesive dispensers known in the art that are capable of dispensing small amounts of adhesives in precise locations in an automated fashion can be used in conjunction with a pick and place machine that positions the spacers on top of the adhesive applied in the gaps 29. In a preferred embodiment, however, a transfer molding process is used to place epoxy between the ancillary electrical devices 22 to serve as gap filler 24. The epoxy can wholly or partially surround the ancillary electrical devices 22 or can simply fill the gaps 29 only. Any suitable epoxy, resin or the like 24 can be used that is capable of mechanically and rigidly bonding the selected ancillary electrical devices 22 together. By way of example, epoxy with embedded silica particles may be employed as the gap filler 24. Regardless of the particular gap filler 24 used, be it epoxy, a mechanical filler such as plastic or combinations thereof, it is preferred that the gap filler 24 have a coefficient of thermal expansion that is close to, or identical to, that of the substrate 12, such as within 50% of the coefficient of thermal expansion of the substrate (i.e, ±50%).

The resulting stiffening member 20 is a rigid member that provides structural stiffness enhancement to the substrate 12. The stiffening member 20 is formed from a predetermined plurality of discrete ancillary electrical devices 22, such as passive devices, that are mechanically coupled to each other by way of the gap filler 24. The discrete ancillary electrical devices 22 are preferably serially connected to each other in a linear arrangement, preferably a straight linear arrangement. Of course, parallel arrangements of multiple serial configurations are possible as well. Contacts 28 on the stiffening member 20 are mechanically coupled to the substrate 12 by way of a plurality of contact points 26, which may be provided by, for example, solder, electrically conductive adhesive or any other suitable means, and which also electrically connect the individual ancillary electrical devices 22 to their respective traces 14 and thus to their corresponding host electrical components 59. Hence, the stiffening member 20 serves two purposes: 1) to provide structural rigidity to the substrate, and 2) to provide ancillary electrical support functions for the host components 59. Simply by way of example, each of the ancillary electrical devices 22 can be a resistor or a capacitor that is used to perform a typical ancillary support function, such as tie a signal line to a voltage source, prevent ringing on a signal line, or decouple a signal line from a power line.

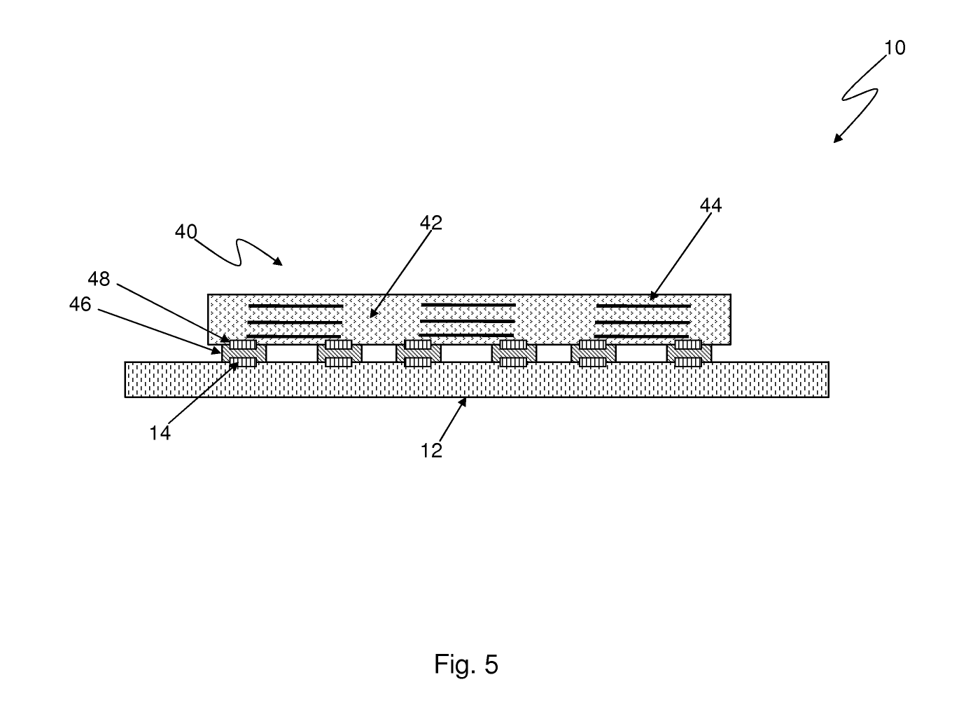

Embodiment stiffening members are not limited to discrete components coupled with gap fillers, however. A suitable embodiment stiffening member may also be created from embedded ancillary electrical devices. An example of this is shown in FIGS. 3 and 5. A plurality of ancillary electrical devices 44 are embedded within a packaging matrix 42 in preferably a serial arrangement to form a rigid, embedded stiffening member 40, which is preferably straight in shape and made from passive devices 44. The embodiment stiffening member 40 can be treated like a standard electrical component and placed on the substrate 12 in a standard manner, such as by way of a pick and place machine. Contacts 48 for the ancillary electrical devices 44 of the stiffening member 40 are aligned with corresponding traces 14 on the substrate 12 and then electrically and mechanically coupled thereto by way of solder, electrically conductive adhesive or the like 46. The stiffening member 40 thus serves to increase the stiffness of the substrate 12 as well as serving as an ancillary electrical component for the host electrical components 59. As in the previous embodiment, a subset 44 of the ancillary electrical devices 11 can first be identified based on, for example, their flexibility of arrangement with respect to their respective host components 59, their structural stiffness, size or shape and then selected for use as the ancillary electrical devices 44 for the embodiment stiffening member 40. The size and shape of the stiffening member 40 is determined, and then the selected ancillary electrical devices 44 are prepackaged into the embodiment stiffening member 40 in accordance with this size and shape. The packaging matrix 42 into which the selected ancillary devices 44 are embedded forms a monolithic piece, such as by embedding the devices 44 in ceramic, to provide the embodiment stiffening member 40 having the predetermined shape, which is typically straight, and which has a stiffness that exceeds that of the substrate 12. The packaging matrix 42 also preferably has a coefficient of thermal expansion that is close to (±50%), or identical to, that of the substrate 12. Once properly positioned over the substrate 12, solder 46 or the like is used to mechanically and electrically couple each contact 48 of the stiffening member 40 to its trace 14, and thereafter the embodiment stiffening member 40 serves as both an ancillary electrical component for the circuit 10, providing electrical support functions for the host electrical components 59, and as stiffening enhancement for the substrate 12.

As shown in FIG. 3, the embodiment stiffening members 20, 40 preferably extend across at least 60% of any linear dimension (i.e., width W, length L) of the substrate 12. It will be appreciated that although solder or other electrically conductive bonding methods may be used to simultaneously mechanically and electrically couple the stiffening members 20, 40 to the substrate 12, it is also possible to have other, separate, arrangements for the mechanical connections and the electrical connections. For example, a non-conductive bonding agent, such as epoxy, may be used to bond portions of the stiffening members 20, 40 to the substrate 12 to provide the primary points of mechanical connection, while solder or electrically conductive adhesive may be used primarily for electrical connections only. It should also be appreciated that in some embodiments the embodiment stiffening members may extend across as little as 10% of the substrate 12.

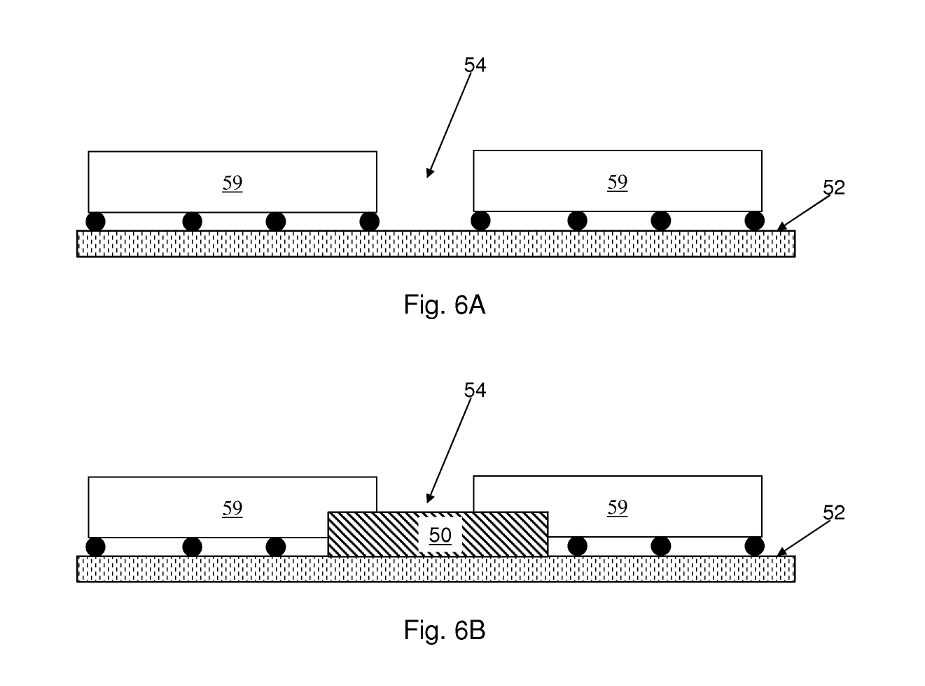

In some embodiments a stiffening member may be configured and positioned so as to protect a specific solder joint on the substrate 12. By way of example, as shown in FIG. 6A, risk or warpage occurs in the gap 54 between pairs of large components 59 that have fine pitch interconnects. In particular, the substrate 52 can suffer warpage between the components 59 after cooling from a solder reflow process. To solve this problem, as shown in FIG. 6B, an embodiment stiffening member 50 that bridges this gap 54 between the components 59 can protect the electrical connections at the edges of the large components. The stiffening member 50 in this embodiment extends adjacent to components 59 as shown and extends across a distance defined by gap 54. In some embodiments, a single stiffening member can be provided on only one side of the components 59. However, in other embodiments, a second stiffening member (not shown) can also be used, disposed on a side of the components 59 opposed from the first stiffening member 50. The second stiffening member 50 can also extend adjacent components 59, and across a distance defined by the gap 54. The stiffening member 50 is advantageously composed of electrical components and spacers as in FIG. 4 or embedded components as in FIG. 5.

An advantage of the embodiment stiffening members 20, 40, 50 is that they serve as actual electrical components of the circuit, and thus are not a mere additional component that would otherwise increase production costs. Further, they do not increase the overall thickness of the circuit 10. Hence, by functioning as both ancillary electrical components and stiffening devices, embodiment stiffening members enable reduced manufacturing costs without increasing the profile of the circuit.

Applicants present certain theoretical aspects above that are believed to be accurate that appear to explain observations made regarding embodiments of the invention. However, embodiments of the invention may be practiced without the theoretical aspects presented. Moreover, the theoretical aspects are presented with the understanding that Applicants do not seek to be bound by the theory presented.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular embodiments only and is not intended to be limiting of the invention. As used herein, the singular forms “a”, “an” and “the” are intended to include the plural forms as well, unless the context clearly indicates otherwise. Furthermore, to the extent that the terms “including”, “includes”, “having”, “has”, “with”, or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

What is claimed is:

1. An electrical system comprising:
a substrate;
a plurality of electrical components mounted on the substrate and electrically coupled to traces on the substrate; and
at least a stiffening member mechanically coupled to the substrate and increasing the stiffness of the substrate, said stiffening member electrically connected to at least one of the electrical components, the stiffening member comprising a plurality of ancillary electrical devices, the ancillary electrical devices being mechanically bonded to each other with gap filler to form the stiffening member, the gap filler having a coefficient of thermal expansion that is within 50% of the coefficient of thermal expansion of the substrate.

2. The electrical circuit of claim 1 wherein the stiffening member comprises a plurality of electrical contacts electrically coupled to corresponding ancillary electrical devices of the stiffening member, and the electrical contacts are soldered to corresponding traces on the substrate to electrically connect the ancillary electrical devices to the at least one of the electrical components.

3. The electrical circuit of claim 1 wherein the plurality of ancillary electrical devices are discrete passive components.

4. The electrical device of claim 1 wherein the stiffening member extends across at least 60% of the substrate.

5. A method for increasing the stiffness of an electrical substrate, the electrical substrate supporting an electrical circuit comprising at least a host component and ancillary electrical devices, the method comprising:
mechanically connecting a plurality of the ancillary electrical devices to the substrate at locations on the substrate corresponding to a stiffening device for the substrate;
electrically connecting the plurality of the ancillary devices to the at least a host component; and
disposing gap filler into gaps between the plurality of the ancillary devices to mechanically connect the plurality of the ancillary devices together to form the stiffening device for the substrate.

6. The method of claim 5 wherein solder or electrically conductive adhesive is used to simultaneously mechanically and electrically connect the plurality of the ancillary devices to the substrate and to the at least a host component, respectively.

7. The method of claim 6 comprising soldering or adhering contacts of the plurality of the ancillary devices to traces on the substrate.

8. The method of claim 7 further comprising:
identifying the location of the stiffening device on the substrate; and
routing traces on the substrate to correspond to the respective positions of the plurality of the ancillary devices.

9. The method of claim 5 wherein the plurality of the ancillary devices are discrete electrical devices.

10. The method of claim 5 wherein the gap filler has a coefficient of thermal expansion that is within 50% of the coefficient of thermal expansion of the substrate.

11. A method for increasing the stiffness of an electrical substrate, the electrical substrate supporting an electrical circuit comprising at least a host component and ancillary electrical devices, the method comprising:
identifying a location for a stiffening device on the substrate;
selecting a plurality of the ancillary electrical devices for positioning on the substrate within the identified location for the stiffening device;
routing traces on the substrate for the plurality of the ancillary electrical devices to electrically connect the plurality of the ancillary electrical devices to the at least a host device;
causing the plurality of the ancillary electrical devices to be embedded within a packaging matrix to form a monolithic component having a stiffness greater than that of the substrate to form the stiffening device; and
using solder to mechanically and electrically connect the stiffening device to the traces on the substrate at the identified location for the stiffening device.

12. The method of claim 11 wherein the packaging matrix has a coefficient of thermal expansion that is within 50% of the coefficient of thermal expansion of the substrate.

13. The method of claim 11 wherein the selected plurality of ancillary devices are passive electrical devices that provide electrical support functions for the at least a host component.
